(19) United States
(12) Patent Application Publication
(10) Pub. No.: US 2006/0228652 A1
(43) Pub. Date: Oct. 12, 2006

(54) Method of fabricating flash memory device

(75) Inventor: Sung Min Hwang, Kyeongki-do (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor, Inc., Kyeongki-do (KR)

(21) Appl. No.: 11/400,001

(22) Filed: Apr. 7, 2006

(30) Foreign Application Priority Data
Apr. 11, 2005 (KR) 10-2005-30016

(51) Int. Cl. G03F 7/26

(52) U.S. Cl. 430/313; 430/311; 430/961

(57) ABSTRACT

A method of fabricating a memory device includes forming first and second gate stacks, each gate stack having a floating gate and a control gate. A contact plug comprising metal is formed to contact a doped region provided between the first and second gate stacks. A first insulation layer is formed over the contact plug. A dual-purpose layer is formed over the first insulation layer, the dual purpose layer serving as an anti-reflective coating and an etch-stop layer. A second insulation layer is formed over the dual-purpose layer. A patterned photoresist layer is formed over the second insulation layer, the patterned photoresist layer defining an opening that overlies the contact plug. The second insulation layer is etched using the patterned photoresist layer, so that a portion of the second insulation layer provided below the opening of the patterned photoresist is etched to form a trench.

### BACKGROUND

The present invention relates to a method of fabricating a flash memory device. More particularly, the present invention relates to a method of fabricating a flash memory device in which the margin of a photolithography process can be improved upon formation of a trench mask.

Many flash memory devices are highly-integrated devices that are made using 90 nm technology or less. As the devices are made smaller, the resistance problem becomes more serious. For this reason, a contact or gate line is formed generally using a metal-based material such as tungsten (W) instead of polysilicon (poly-si).

However, the light derived from KrF (248 nm) or ArF (193 nm), which is used as an exposure light in a subsequent photolithography process, tends to diffuse severely (or “diffused reflection”) when it contacts a metal-based material. Using such a material as an underlying contact, a gate line or the like leads to a reduced margin during the photolithography process.

For example, in the NAND flash memory device, the process of forming a gate, the process of forming a first interlayer insulating layer made of a PE-TEOS oxide layer, the process of forming a source contact in the first interlayer insulating layer, the process of forming a second interlayer insulating layer made of a PE-TEOS oxide layer and the process of forming a drain contact in the second and first interlayer insulating layers are first performed. An etch-stop layer made of oxynitride (SiNₓ) and a trench oxide layer are then formed. A photolithography process is then carried out in order to form trenches in the trench oxide layer and the etch-stopper layer.

If one (or more) of the gate, the source contact and the drain contact are formed using the metal-based material, however, the underlying metal-based material causes the exposure light to generate diffused reflection, thereby reducing the margin of the photolithography process.

FIG. 1 is a view illustrating a reflection phenomenon between two media (a medium 1 and a medium 2) with different refractive indices when the extinction coefficient (k) is sufficiently smaller than the refractive index (n).

Assuming that the refractive index of the medium 1 is n1 and the refractive index of the medium 2 is n2 in FIG. 1, the reflectivity (R) occurring at the interface of the medium 1 and the medium 2 can be expressed as in the following Equation.
R=(n1−n2)/(n1+n2) [Equation]

The oxide layer and the nitride layer have a refractive index of about 1.5 to 1.6 and tungsten (W) has a refractive index of 0.2 to 0.4. From the Equation, it can be seen that the reflectivity at the interface of the trench oxide layer and the etch-stop layer or at the interface of the etch-stop layer and the second interlayer insulating layer is not high, but the reflectivity at the interface of the first interlayer insulating layer and tungsten is very high.

Light that has experienced diffused reflection at the interface of the first interlayer insulating layer and tungsten results in reducing the margin of the photolithography process. Accordingly, pattern collapse or pattern failure, such as a thin line, may occur when patterning the trench oxide layer and the etch-stop layer.

In the related art, to prevent the photolithography process margin reduction from the diffused reflection, a Bottom Anti-Reflective Coating (hereinafter referred to as “BARC”) layer, such as an organic BARC material or an inorganic BARC material, is formed below the photomask in order to minimize the effects of the diffused reflection. To secure the photolithography process margin using the BARC layer, however, the BARC layer should be relatively thick.

If the BARC layer is too thick, this may be problematic since the etch target will be increased correspondingly. This requires the photomask to be thicker, which in turn causes the photomask to have a high aspect ratio that increases the danger of the photomask collapse.

### SUMMARY OF THE INVENTION

An embodiment of the present invention relates to a method of fabricating a flash memory device, in which the photolithography process margin is improved.

Another embodiment of the present invention relates to a method of fabricating a flash memory device, in which pattern failure is prevented.

Still another embodiment of the present invention relates to a method of fabricating a flash memory device, in which failure such as the collapse of a photomask is prevented by reducing the aspect ratio of the photomask.

A method of fabricating a flash memory device according to an exemplary embodiment of the present invention includes forming an anti-reflection and etch-stop layer on a semiconductor substrate in which a lower pattern is formed, forming an insulation layer on the anti-reflection and etch-stop layer, forming a photoresist on the insulation layer, patterning the photoresist, and etching the insulation layer and the anti-reflection and etch-stop layer using the patterned photoresist as a mask, thereby forming the depth of trenches.

The anti-reflection and etch-stop layer may be formed using an inorganic BARC material.

The insulation layer may be formed using an oxide layer and the anti-reflection, and etch-stop layer (or etch stopper) may be formed using a SiON layer.

The method may further include the step of forming the BARC layer on the insulation layer before the photoresist is formed.

In one implementation, a method of fabricating a semiconductor device includes forming a metal contact plug contacting a doped region provided between two gate structures; forming an anti-reflective and etch-stop layer over the metal contact plug and the gate structures; forming an insulation layer over the anti-reflective and etch-stop layer; providing a patterned photoresist layer over the insulation layer, the patterned photoresist layer defining an opening that lies above the metal contact plug; and etching the insulation layer and the anti-reflective and etch-stop layer using the patterned photoresist as a mask to form a trench overlying the metal contact plug.

The insulation layer is etched using a first etch gas, and the anti-reflective and etch-stop layer is etched using a second gas. The patterned photoresist layer is removed after etching the insulation layer and the anti-reflective and etch-stop layer.

In another implementation, a method of fabricating a memory device includes forming first and second gate stacks, each gate stack having a floating gate and a control gate. A contact plug comprising metal is formed to contact a doped region provided between the first and second gate stacks. A first insulation layer is formed over the contact plug. A dual-purpose layer is formed over the first insulation layer, the dual purpose layer serving as an anti-reflective coating and an etch-stop layer. A second insulation layer is formed over the dual-purpose layer. A patterned photoresist layer is formed over the second insulation layer, the patterned photoresist layer defining an opening that overlies the contact plug. The second insulation layer is etched using the patterned photoresist layer, so that a portion of the second insulation layer provided below the opening of the patterned photoresist is etched to form a trench.

A portion of the dual-purpose layer that is exposed by the etching of the portion of the second insulation layer is etched. The portion of the dual-purpose layer is etched at least until the first insulation layer is substantially exposed.

### BRIEF DESCRIPTION OF THE DRAWINGS

A more compete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a view illustrating a reflection phenomenon between two media with different refractive indices;

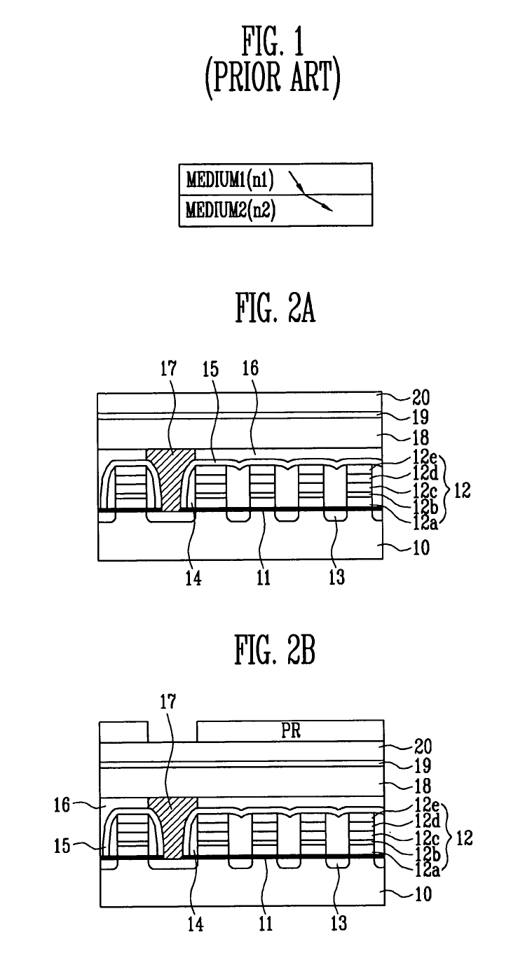

FIGS. 2A to 2C are cross-sectional views illustrating a method of fabricating a flash memory device according to a first embodiment of the present invention;

FIGS. 3A to 3C are cross-sectional views illustrating a method of fabricating a flash memory device according to a second embodiment of the present invention;

FIG. 4 shows the simulation results of a cross section of a photoresist (PR) when the etch stopper in the trench process is SiN (the related art) and SiON (the present embodiment); and

FIG. 5 shows the reflectivity of a substrate according to a thickness of the etch stopper when the etch stopper in the trench process is SiN (the related art) and SiON (the present embodiment).

### DETAILED DESCRIPTION OF EMBODIMENTS

In the following detailed description, only certain exemplary embodiments of the present invention have been shown and described simply by way of illustration. As those skilled in the art will realize, the described embodiments may be modified in various different ways, all without departing from the spirit or scope of the present invention. Accordingly, the drawings and description are to be regarded as illustrative in nature and not restrictive. Like reference numerals designate like elements in the present application.

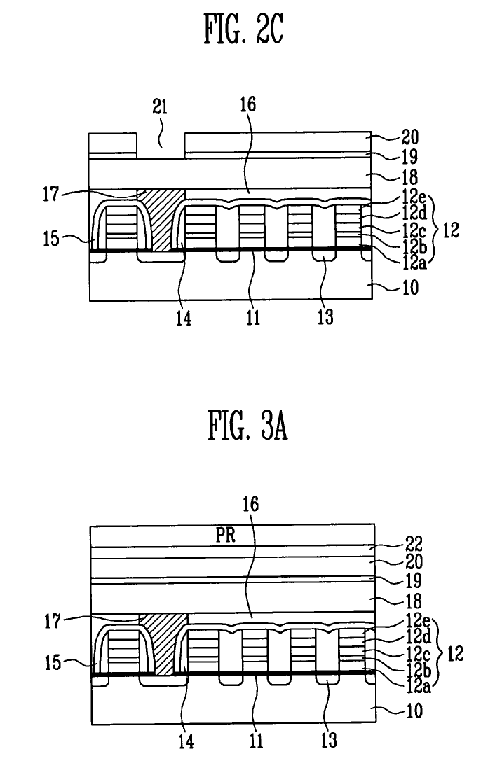

FIGS. 2A to 2C are cross-sectional views illustrating a method of fabricating a flash memory device according to a first embodiment of the present invention.

Referring first to FIG. 2A, a tunneling oxide layer 11 is formed on a semiconductor substrate 10. A plurality of gates 12 are formed on the tunneling oxide layer 11. Each gate has a floating gate 12a, an interlayer dielectric layer 12b, a polysilicon layer 12c for a control gate, a tungsten silicide (WSix) layer 12d and a hard mask layer 12e. Impurity ions are injected into the semiconductor substrate 10 using the gates 12 (or gate stacks) as a mask, thereby forming source and drain junctions 13. Spacers 14 are formed on the sidewalls of the gates 12.

A buffer oxide layer (not shown) and a sacrificial nitride layer 15 are then sequentially formed on the entire surface. A first interlayer insulating layer 16 is then formed and then polished. The first interlayer insulating layer 16, the sacrificial nitride layer 15 and the buffer oxide layer and the tunneling oxide layer 11 are etched to expose the source junctions, thereby forming source contact holes. Metal or polysilicon layer is filled into the source contact holes to form source contact plugs 17. The use of metal to fill the contact holes reduces the resistance of the source contact plug 17, which becomes important as the devices shrink and the contact plugs become smaller.

Thereafter, a second interlayer insulating layer 18 is deposited on the entire surface and then polished.

At this time, though not shown in the drawings, the second interlayer insulating layer 18, the first interlayer insulating layer 16, the sacrificial nitride layer 15 and the buffer oxide layer and the tunneling oxide layer 11 are etched to expose the drain junctions, thus forming drain contact holes. Each of the drain contact holes is filled with polysilicon or a metal film to form a drain contact plug. The use of metal film reduces the resistance of the drain contact plug.

If the source contact plug 17 or the drain contact plug is formed using metal, the exposure light used during the photolithography process to form a trench experiences diffused reflection due to these metal plugs, thereby causing pattern failure.

For this reason, an anti-reflective coating or layer 19 is formed, e.g., an inorganic BARC material, to prevent the diffused reflection during the photolithography process. The layer 19 also serves as an etch-stop layer during the etch process to form the trenches. The layer 19 serves a dual purpose unlike the conventional etch-stop layer that is formed using oxynitride (SiN). An oxide layer 20 for the trench is formed on the anti-reflective and etch-stop layer 19.

Referring next to FIG. 2B, a photoresist (PR) is coated on the oxide layer 20. The photoresist (PR) is patterned by an exposure and development process so that the oxide layer 20 is provided with openings to define trenches overlying the source contact plug 17 and the drain contact plugs (not shown).

Although the underlying contact and drain plugs are made of metal, the diffused reflection phenomenon of the exposure light is minimized by the anti-reflective/etch-stopper layer 19. It is therefore possible to significantly reduce the pattern failure resulting from the small photolithography process margin.

As shown in FIG. 2C, the oxide layer 20 and the anti-reflective/etch-stop layer 19 are etched using the patterned photoresist (PR) as a mask, thus forming a trench 21.

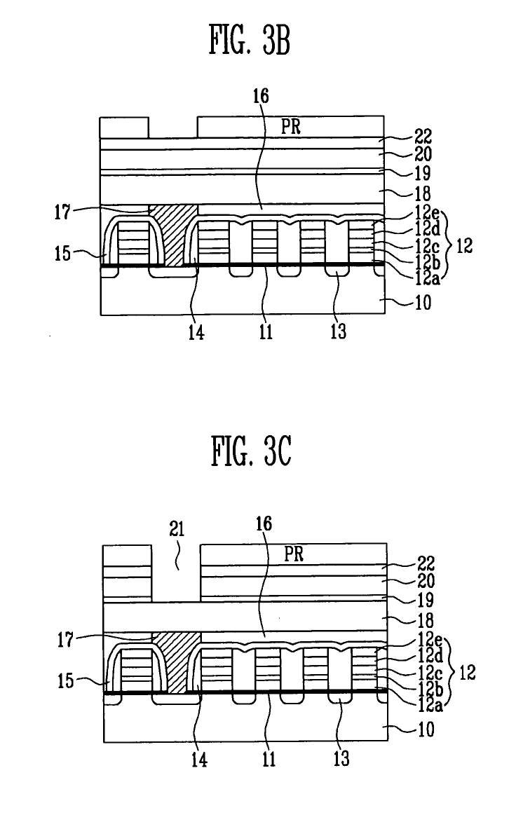

FIGS. 3A to 3C are cross-sectional views illustrating a method of fabricating a flash memory device according to a second embodiment of the present invention.

As shown in FIG. 3A, a tunneling oxide layer 11 is formed on a semiconductor substrate 10. A plurality of gates 12 are formed on the tunneling oxide layer 11. Each of these gate stacks 12 has a floating gate 12a, an interlayer dielectric layer 12b, a polysilicon layer 12c for a control gate, a tungsten silicide (WSix) layer 12d and a hard mask layer 12e. Impurity ions are then injected into the semiconductor substrate 10 using the gates 12 as a mask, thereby forming source and drain junctions 13. Spacers 14 are formed on the sidewalls of the gates 12.

A buffer oxide layer (not shown) and a sacrificial nitride layer 15 are then sequentially formed on the entire surface. A first interlayer insulating layer 16 is then formed over the entire surface and fully covers the gates 12. The insulating layer 16 is polished to provide a smooth and uniform surface for the subsequent photolithography process. The first interlayer insulating layer 16, the sacrificial nitride layer 15 and the buffer oxide layer and the tunneling oxide layer 11 are etched to form source contact holes. Each of the source contact holes is filled with metal or polysilicon to form source contact plugs 17. The use of the metal reduces the resistance of the source contact plug 17, which becomes important as the devices shrink and the contact plugs become smaller.

Thereafter, a second interlayer insulating layer 18 is deposited on the entire surface and then polished.

At this time, though not shown in the drawings, the second interlayer insulating layer 18, the first interlayer insulating layer 16, the sacrificial nitride layer 15 and the buffer oxide layer and the tunneling oxide layer 11 are etched to from drain contact holes. Each of the drain contact holes is filled with polysilicon or metal to form a drain contact plug. The use of metal reduces the resistance of the drain contact plug as with the source contact plug.

If the source contact or the drain contact plug is formed using metal, the exposure light that is used during the photolithography process to form a trench experiences diffused reflection and may cause the pattern failure because the trench is aligned over the metal contact plug.

For this reason, an anti-reflective/etch-stopper layer 19 is formed over the second interlayer insulating layer 18. In the present embodiment, the layer 19 is made of inorganic BARC material. The layer 19 is used to minimize the diffused reflection during the photolithography process. The layer 19 also serves as an etch-stop layer during the etch process to form the trenches. The layer 19 serves a dual purpose unlike the conventional etch-stop layer that is formed using oxynitride (SiN). An oxide layer 20 for the trench is formed on the anti-reflective/etch-stop layer 19.

Referring to FIG. 3B, a BARC layer 22 is formed on the oxide layer 20 (or trench oxide layer) in order to minimize the diffused reflection of the exposure light. The BARC layer 22 may be formed using an organic or inorganic BARC material.

The BARC layer 22 and the anti-reflective/etch-stopper layer 19 are used together to minimize the diffused reflection. Accordingly, the thickness of the BARC layer 22 is reduced when compared to the conventional technology. A photoresist (PR) layer is coated on the BARC layer 22.

Since the BARC layer 22 having a reduced thickness may be used, the total etch target is reduced. The thickness of the photoresist (PR) layer may consequently be reduced. This avoids the photoresist from having a high aspect ratio, thereby reducing the danger of the photoresist (PR) collapse.

The photoresist (PR) layer is patterned through exposure and development processes to provide openings over the contact plugs. Portions of the BARC layer 22 that are exposed by the photoresist openings are etched. The oxide layer 20 and the anti-reflective/etch-stop layer 19 are etched form to trenches 21 (see FIG. 3C) that overly the contact plugs.

In the second embodiment of the present invention, the BARC layer 22 is added. Therefore, the influence of diffused reflection when patterning the photoresist (PR) can be further reduced when compared with the first embodiment.

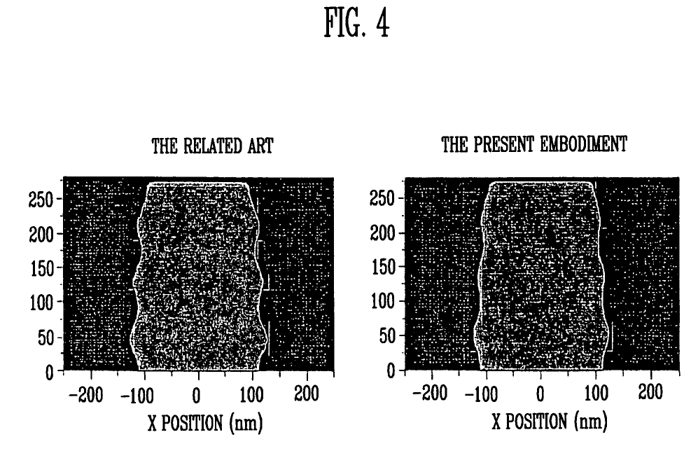

FIG. 4 shows the simulation results of the cross section of the photoresist (PR) layer when the etch-stop layer in the trench process is SiN (the related art) and SiON (the present embodiment)

From FIG. 4, it can be seen that the use of SiON reduces the standing wave effect more than SiN. If the standing wave effect is small, it is advantageous during the patterning process. To reduce the standing wave effect, a post-expose baking process may be additionally carried out.

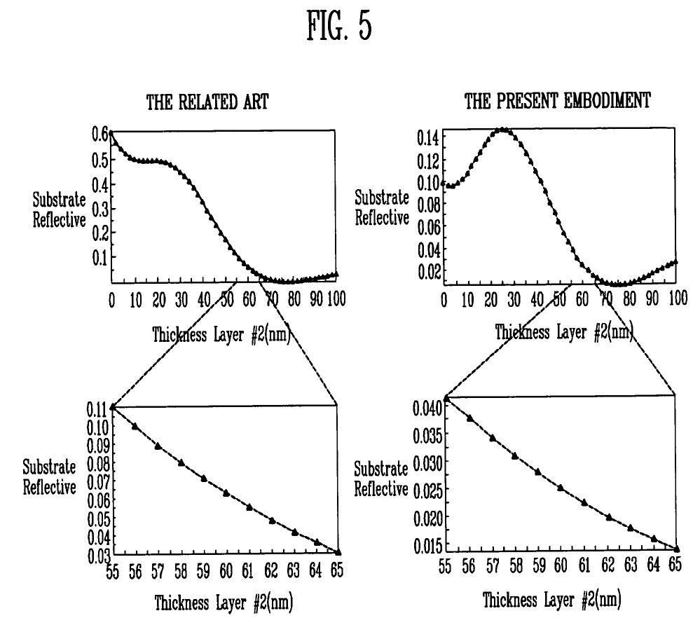

FIG. 5 shows the reflectivity of a substrate according to the thickness (thickness layer #2) of the etch-stop layer when the etch-stop layer in the trench process is SiN (the related art) and SiON (the present embodiment).

From FIG. 5, it can be seen that the reflectivity was improved 200% or more when SiON is used rather than SiN.

For example, assuming that the thickness of SiN and SiON is 65 nm, the reflectivity is 0.03% when SiN is used. However, the reflectivity can be lowered up to 0.015% when SiON is used. In addition, the efficiency can be further enhanced according to the thickness of SiN or SiON.

As described above, the present invention may have the following advantages.

First, the etch-stop layer of the trench process serves as both an etch-stopper layer and as an anti-reflective layer. Accordingly, the diffused reflection of the exposure light due to an underlying metal layer can be minimized. It is therefore possible to reduce the occurrence of the failure patterns due to the diffused reflection.

Second, the BARC layer that is relatively may be used to negate the diffused reflection by using such a layer with the anti-reflective/etch-stop layer. It is thus possible to reduce the thickness of the photoresist, which makes it possible to use a photoresist layer that is not as thick. This prevents the photoresist layer from having a high aspect ratio and the resulting photoresist collapse or thin line.

Third, since the standing wave effect can be reduced, the photoresist layer may be patterned more easily.

While the invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of fabricating a semiconductor device, the method comprising:
forming a metal contact plug contacting a doped region provided between two gate structures;
forming an anti-reflective and etch-stop layer over the metal contact plug and the gate structures;
forming an insulation layer over the anti-reflective and etch-stop layer;
providing a patterned photoresist layer over the insulation layer, the patterned photoresist layer defining an opening that lies above the metal contact plug; and
etching the insulation layer and the anti-reflective and etch-stop layer using the patterned photoresist as a mask to form a trench overlying the metal contact plug.

2. The method as claimed in claim 1, wherein the anti-reflective and etch-stop layer is formed using an inorganic Bottom Anti-Reflective Coating (hereinafter referred to as “BARC”) material.

3. The method as claimed in claim 1, wherein the insulation layer comprises oxide and the anti-reflective and etch-stop layer comprises SiON.

4. The method as claimed in claim 1, further comprising:
forming a Bottom Anti-Reflective Coating (BARC layer) between the insulation layer and the photoresist layer.

5. The method of claim 1, wherein the semiconductor device is a flash memory device, the doped region is a source or drain region.

6. The method of claim 1, further comprising:
forming a dielectric layer over the metal contact plug, so that the dielectric layer is provided between the insulation layer and the metal contact plug.

7. The method of claim 1, wherein the insulation layer is etched using a first etch gas and the anti-reflective and etch-stop layer is etched using a second gas.

8. The method of claim 1, wherein the patterned photoresist layer is removed after etching the insulation layer and the anti-reflective and etch-stop layer.

9. A method of fabricating a memory device, the method comprising:
forming first and second gate stacks, each gate stack having a floating gate and a control gate;
forming a contact plug comprising metal to contact a doped region provided between the first and second gate stacks;
forming a first insulation layer over the contact plug;
forming a dual-purpose layer over the first insulation layer, the dual purpose layer serving as an anti-reflective coating and an etch-stop layer;
forming a second insulation layer over the dual-purpose layer;
forming a patterned photoresist layer over the second insulation layer, the patterned photoresist layer defining an opening that overlies the contact plug; and
etching the second insulation layer using the patterned photoresist layer, so that a portion of the second insulation layer provided below the opening of the patterned photoresist is etched to form a trench.

10. The method of claim 9, further comprising:
etching a portion of the dual-purpose layer that is exposed by the etching of the portion of the second insulation layer.

11. The method of claim 10, wherein the portion of the dual-purpose layer is etched at least until the first insulation layer is substantially exposed.

12. The method as claimed in claim 9, wherein the dual-purpose layer comprises an inorganic Bottom Anti-Reflective Coating (hereinafter referred to as “BARC”) material.

13. The method as claimed in claim 9, wherein the first and second insulation layers comprise oxide and the dual-purpose layer comprises SiON.

14. The method as claimed in claim 9, further comprising:
forming a Bottom Anti-Reflective Coating layer over the second insulation layer before forming the photoresist layer.

15. The method of claim 9, wherein the second insulation layer is etched using a first etch gas and the dual-purpose layer is etched using a second gas.

16. The method of claim 9, wherein the patterned photoresist layer is removed after etching the insulation layer and the dual-purpose layer.
